(19) United States
(12) Patent Application Publication
(10) Pub. No.: US 2013/0105440 A1
(43) Pub. Date: May 2, 2013

(54) NANOCOMPOSITE NEGATIVE PHOTOSENSITIVE COMPOSITION AND USE THEREOF

(71) Applicants: Ping-Hung LU, Bridgewater, NJ (US); Chunwei CHEN, Bridgewater, NJ (US); Stephen MEYER, Saylorsburg, PA (US)

(72) Inventors: Ping-Hung LU, Bridgewater, NJ (US); Chunwei CHEN, Bridgewater, NJ (US); Stephen MEYER, Saylorsburg, PA (US)

(73) Assignee: AZ ELECTRONIC MATERIALS USA CORP., SOMERVILLE, NJ (US)

(21) Appl. No.: 13/286,755

(22) Filed: Nov. 1, 2011

(51) Int. Cl. C23F 1/02; G03F 7/075; G03F 7/09; G03F 7/032; B82Y 30/00

(52) U.S. Cl. 216/41; 430/270.1; 430/281.1; 977/773

(57) ABSTRACT

The present invention relates to a negative photosensitive composition suitable for image-wise exposure and development as a negative photoresist comprising a negative photoresist composition and an inorganic particle material having an average particle size equal or greater than 10 nanometers, wherein the thickness of the photoresist coating film is less than 5 microns. The negative photoresist composition is selected from (1) a composition comprising (i) a resin binder, (ii) a photoacid generator, and (iii) a cross-linking agent; or (2) a composition comprising (i) a resin binder, (ii) optionally, addition-polymerizeable, ethylenically unsaturated compound(s) and (iii) a photoinitiator; or (3) a composition comprising (i) a photopolymerizable compound containing at least two pendant unsaturated groups; (ii) ethylenically unsaturated photopolymerizable polyalkylene oxide hydrophilic compound(s); and (iii) a photoinitiator. The invention also relates to a process of forming an image using the novel photosensitive composition.

### TECHNICAL FIELD

The present invention relates to a novel photosensitive composition suitable for image-wise exposure and development as a negative photoresist comprising a negative photoresist composition and an inorganic particle material having an average particle size equal or smaller than 100 nanometers, wherein the thickness of the photoresist coating film is less than 5 microns. The invention also relates to a process of forming a pattern.

### DESCRIPTION

Photoresist compositions are used in microlithography processes for making miniaturized electronic components such as in the fabrication of computer chips and integrated circuits. Generally, in these processes, a coating of film of a photoresist composition is first applied to a substrate material, such as silicon wafers used for making integrated circuits. The coated substrate is then baked to evaporate any solvent in the photoresist composition and to fix the coating onto the substrate. The baked coated surface of the substrate is next subjected to an image-wise exposure to radiation. This radiation exposure causes a chemical transformation in the exposed areas of the coated surface. Visible light, ultraviolet (UV) light, electron beam and X-ray radiant energy are radiation types commonly used today in microlithographic processes. After this image-wise exposure, the coated substrate is treated with a developer solution to dissolve and remove either the radiation-exposed or the unexposed areas of the coated surface of the substrate.

When negative-working photoresist compositions are exposed image-wise to radiation, the areas of the photoresist composition exposed to the radiation become less soluble to a developer solution (e.g. a cross-linking reaction occurs) while the unexposed areas of the photoresist coating remain relatively soluble in such a solution. Thus, treatment of an exposed negative-working photoresist with a developer causes removal of the non-exposed areas of the photoresist coating and the creation of a negative image in the coating. A desired portion of the underlying substrate surface is uncovered.

After this development operation, the now partially unprotected substrate may be treated with a substrate-etchant solution, plasma gases, or have metal or metal composites deposited in the spaces of the substrate where the photoresist coating was removed during development. The areas of the substrate where the photoresist coating still remains are protected. Later, the remaining areas of the photoresist coating may be removed during a stripping operation, leaving a patterned substrate surface. In some instances, it is desirable to heat treat the remaining photoresist layer, after the development step and before the etching step, to increase its adhesion to the underlying substrate.

Aqueous developable photopolymerizable compositions are of especial interest for negative working photoresist compositions. The polymeric binders for such compositions can contain acidic functionality so that the binder polymer is soluble in alkaline aqueous solution and thereby renders the photopolymerizable composition developable in alkaline aqueous solutions. Those in the art will also appreciate that resin binders can be used which are then developable using non-aqueous solvents.

Additives, such as surfactants, are often added to a photoresist composition to improve the coating uniformity of the photoresist film where the film thickness is less than 5 microns, especially to remove striations within the film. Various types of surfactants are added typically at levels ranging from about 5 ppm to about 200 ppm.

In the manufacture of Light emitting diodes (LED) creation of surface texture (roughening) is employed to improve light extraction from the high index LED to the outside. The creation of surface texture or roughening (undulations on the surface) improves the chances of light making it out of the high index of refraction medium by offering to the exiting light more surfaces at which the angle of the light with the surface is such that total internal reflection does not occur. Typically, three methods are employed to accomplish this as follows: roughening of the surface of the LED induced chemically or mechanically; patterning of the substrate by using lithography and a wet or reactive ion etching of an underlying chemically vapor deposited oxide to create bumps which are 1-5 microns in size with a 5-10 micron pitch; and, photonic crystals are made at the surface of an LED and are made by a combination of lithography and reactive ion etching to form holes smaller than 1 micron with a periodic or semi periodic pattern.

A specific example is the manufacture of PSS (patterned sapphire substrate) light emitting diodes (LED) consisting of a dense array of bumps that need to be patterned by using a negative photoresist coated on a CVD (chemical vapor deposited) layer of silicon oxide. Typically, the photoresist is used to create the CVD hard mask which is then used to transfer the pattern into the underlying sapphire substrate. Other substrates are patterned in this way such as Si, SiC and GaN.

The applicants of the present invention have unexpectedly found that the addition of nanoparticles to a negative photoresist can provide a significant increase in the plasma etch resistance towards chlorine based plasma, which is used to etch a sapphire substrate. The photoresists containing nanoparticles which increase the plasma etch resistance can be used in films thinner than 5 microns to increase the throughput for the manufacture of PSS LED (light emitting diodes) and reduce the cost of manufacturing by eliminating the need for CVD oxide hard masks. Similarly, the patterning of substrates such as sapphire, GaN, Si and SiC, and the manufacture of photonic crystals would also see an increase in throughput by eliminating the need for a chemical vapor deposition of silicon dioxide as a separate step.

### SUMMARY OF THE INVENTION

The present invention is related to a photosensitive composition suitable for image-wise exposure and development as a negative photoresist comprising a negative photoresist composition and an inorganic particle material having an average particle size equal or smaller than 100 nanometers, wherein the thickness of the photoresist coating film is less than 5 microns. The negative photoresist composition can be selected from (1) a composition comprising (i) a resin binder, (ii) a photoacid generator, and (iii) a cross-linking agent; or (2) a composition comprising (i) a resin binder, (ii) optionally, addition-polymerizeable, ethylenically unsaturated compound(s) and (iii) a photoinitiator; or (3) a composition comprising (i) a photopolymerizable compound containing at least two pendant unsaturated groups; (ii) ethylenically unsaturated photopolymerizable polyalkylene oxide hydrophilic compound(s); and (iii) a photoinitiator. The present invention also relates to a process for using the novel composition for forming an image on a substrate. The imaged substrate can be further dry etched using a gas.

### DETAILED DESCRIPTION OF THE INVENTION

The present invention relate to a novel photosensitive or photoresist composition suitable for image-wise exposure and development as a negative photoresist comprising a negative photoresist composition and an inorganic particle material having an average particle size equal to or less than 100 nanometers, wherein the thickness of the photoresist coating film is less than 5 microns. The negative photoresist composition can be selected from (1) a composition comprising (i) a resin binder, (ii) a photoacid generator, and (iii) a cross-linking agent; or (2) a composition comprising (i) a resin binder, (ii) optionally, addition-polymerizeable, ethylenically unsaturated compound(s) and (iii) a photoinitiator; or (3) a composition comprising (i) a photopolymerizable compound containing at least two pendant unsaturated groups; (ii) ethylenically unsaturated photopolymerizable polyalkylene oxide hydrophilic compound(s); and (iii) a photoinitiator.

Standard photoresist compositions suitable for image-wise exposure and development as a negative photoresist are known and can be used herein.

In certain embodiments of the present invention, the resin binders may comprise a novolak, preferably derived from a substituted phenol such as ortho-cresol; meta-cresol; para-cresol; 2,4-xylenol; 2,5-xylenol; 3,4-xylenol, 3,5-xylenol, thymol and mixtures thereof, that has been condensed with an aldehyde such as formaldehyde. The binder resin may also comprise a poly(vinyl phenol) or copolymers of vinylphenol, such as a poly(para-hydroxystyrene); a poly(para-hydroxy-alpha-methylstyrene; a copolymer of para-hydroxystyrene or para-hydroxy-alpha-methylstyrene and styrene, acetoxystyrene or acrylic acid and/or methacrylic acid; a hydroxyphenylalkyl carbinol homopolymer; or a novolak/poly(vinyl phenol) copolymer. The methods for obtaining novolak resins are well known to those skilled in the art. For example, novolak resins are described in U.S. Pat. No. 3,825,430 where resins can be made from condensation product of phenol, or its derivatives, and formaldehyde. The content of this patent U.S. Pat. No. 3,825,430 is hereby incorporated herein by reference.

Crosslinking agents are those agents which are capable of forming a crosslinked structure under the action of an acid. Some examples of crosslinking agents include aminoplasts such as, for example, glycoluril-formaldehyde resins, melamine-formaldehyde resins, benzoguanamine-formaldehyde resins, and urea-formaldehyde resins. The use of methylated and/or butylated forms of these resins is highly preferred for obtaining long storage life (3-12 months) in catalyzed form. Highly methylated melamine-formaldehyde resins having degrees of polymerization less than two are useful. Monomeric, methylated glycoluril-formaldehyde resins are useful, when needed, with the photoresist composition of the present ivnention. One example is N,N,N,N-tetra(alkoxymethyl)glycoluril. Examples of N,N,N,N-tetra(alkoxymethyl)glycoluril, may include, e.g., N,N,N,N-tetra(methoxymethyl)glycoluril, N,N,N,N-tetra(ethoxymethyl)glycoluril, N,N,N,N-tetra(n-propoxymethyl)glycoluril, N,N,N,N-tetra(1-propoxymethyl)glycoluril, N,N,N,N-tetra(n-butoxymethyl)glycoluril and N,N,N,N-tetra(t-butoxymethyl)glycoluril. N,N,N,N-tetra(methoxymethyl)glycoluril is available under the trademark POWDERLINK from Cytec Industries (e.g., POWDERLINK 1174). Other examples include methylpropyltetramethoxymethyl glycoluril, and methylphenyltetramethoxymethyl glycoluril. Similar materials are also available under the NIKALAC tradename from Sanwa Chemical (Japan).

Other aminoplast crosslinking agents are commercially available from Cytec Industries under the trademark CYMEL and from Monsanto Chemical Co. under the trademark RESIMENE. Condensation products of other amines and amides can also be employed, for example, aldehyde condensates of triazines, diazines, diazoles, guanidines, guanimines and alkyl- and aryl-substituted derivatives of such compounds, including alkyl- and aryl-substituted melamines. Some examples of such compounds are N,N′-dimethyl urea, benzourea, dicyandiamide, formaguanamine, acetoguanamine, ammeline, 2-chloro-4,6-diamino-1,3,5-triazine, 6-methyl-2,4-diamino,1,3,5-triazine, 3,5-diaminotriazole, triaminopyrimidine,2-mercapto-4,6-diamino-pyrimidine, 3,4,6-tris(ethylamino)-1,3,5-triazine, tris(alkoxycarbonylamino)triazine, N,N,N′,N′-tetramethoxymethylurea, methylolbenzoguanamine or alkyl ether compound thereof, such as tetramethylolbenzoguanamine, tetramethoxymethylbenzoguanamine and trimethoxymethylbenzoguanamine; 2,6-bis(hydroxymethyl)-4-methylphenol or alkyl ether compound thereof; 4-tert-butyl-2,6-bis(hydroxymethyl)phenol or alkyl ether compound thereof; 5-ethyl-1,3-bis(hydroxymethyl)perhydro-1,3,5-triazin-2-one (common name: N-ethyldimethyloltriazine) or alkyl ether compound thereof; N,N-dimethyloltrimethyleneurea or dialkyl ether compound thereof; 3,5-bis(hydroxymethyl)perhydro-1,3,5-oxadiazin-4-one (common name: dimethylolurone) or alkyl ether compound thereof; and tetramethylolglyoxazaldiurein or dialkyl ether compound thereof and the like.

Other possible crosslinking agents include: 2,6-bis(hydroxymethyl)-p-cresol and compounds having the following structures:

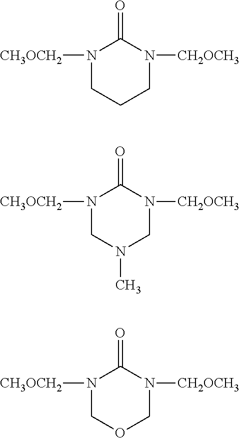

including their analogs and derivatives, such as methylolmelamines, hexamethylolmelamine, pentamethylolmelamine, and tetramethylolmelamine as well as etherified amino resins, for example alkoxylated melamine resins (for example, hexamethoxymethylmelamine, pentamethoxymethylmelamine, hexaethoxymethylmelamine, hexabutoxymethylmelamine and tetramethoxymethylmelamine) or methylated/butylated glycolurils, for example as well as those found in Canadian Patent No. 1 204 547 to Ciba Specialty Chemicals. Other examples include, for example, N,N,N,N-tetrahydroxymethylglycoluril, 2,6-dihydroxymethylphenol, 2,2′6,6′-tetrahydroxymethyl-bisphenol A, 1,4-bis[2-(2-hydroxypropyl)]benzene, and the like, etc. Other examples of crosslinking agents include those described in U.S. Pat. No. 4,581,321 and U.S. Pat. No. 4,889,789, the contents of which are incorporated by reference. Various melamine and urea resins are commercially available under the Nikalacs (Sanwa Chemical Co.), Plastopal (BASF AG), or Maprenal (Clariant GmbH) tradenames.

The crosslinking agent can be used individually or in mixtures with each other. The crosslinking agent is added to the composition in a proportion which provides from about 0.10 to about 2.00 equivalents of crosslinking function per reactive group on the polymer.

Other resin binders can include acid functional monomers and/or oligomers thereof and non-acid functional monomers and/or oligomers thereof and oligomers and/or polymers derived from mixtures of acid functional monomers and non-acid functional monomers, and mixtures thereof. These acid functional monomers and/or oligomers thereof and non-acid functional monomers and/or oligomers thereof and mixtures thereof can also function as addition-polymerizable, ethylenically unsaturated compounds for the present invention.

Examples of acid functional and non-acid functional monomers include monomers such as, for example, and not limited to, acrylic acid, methacrylic acid, maleic acid, maleic anhydride, fumaric acid, fumaric anhydride, citraconic acid, citraconic anhydride, itaconic acid, itaconic anhydride, vinyl carboxylic acid, 2-acrylamido-2-methylpropanesulfonic acid, 2-hydroxyethyl acryloyl phosphate, 2-hydroxypropyl acryloyl phosphate, 2-hydroxy-a-acryloyl phosphate, and the like; esters of acrylic acids, for example, methyl acrylate, methyl methacrylate, hydroxyl ethyl methacrylate, hydroxylethyl acrylate, butyl methacrylate, octyl acrylate, 2-ethoxy ethyl methacrylate, t-butyl acrylate, n-butyl acrylate, 2-ethyl hexylacrylate, n-hexyl acrylate, 2-hydroxyethyl acrylate, 2-hydroxypropyl acrylate, 3-hydroxypropyl, acrylate, 2-hydroxybutyl acrylate, 3-hydroxybutyl acrylate, 4-hydroxybutyl acrylate, 2-hydroxyethyl methacrylate, 2-hydroxypropyl methacrylate, 3-hydroxypropyl methacrylate, 2-hydroxybutyl methacrylate, 3-hydroxybutyl methacrylate, 4-hydroxybutyl methacrylate, allyl acrylate, allyl methacrylate, benzyl acrylate, benzyl methacrylate, cyclohexyl acrylate, cyclohexyl methacrylate, methoxypropylene glycol acrylate, methoxypropylene glycol methacrylate, methoxydiethylene glycol acrylate, methoxydiethylene glycol methacrylate, methoxytripropylene glycol acrylate, methoxytripropylene glycol methacrylate, isobornyl acrylate, isobornyl methacrylate, dicyclopentadienyl acrylate, dicyclopentadienyl methacrylate, 2-hydroxy-3-phenoxypropyl acrylate, 2-hydroxy-3-phenoxypropyl methacrylate, mevaloniclactone methacrylate, 2-methyladamantyl methacrylate, isoadamantyl methacrylate, 3-hydroxy-1-methacryloxyadamatane, 3,5-dihydroxy-1-methacryloxyadamantane, β-methacryloxy-γ-butyrolactone, α-methacryloxy-γ-butyrolactone,1,5-pentanediol diacrylate, N,N-diethylaminoethyl acrylate, ethylene glycol diacrylate, 1,3-propanediol diacrylate, decamethylene glycol diacrylate, decamethylene glycol dimethacrylate, 1,4-cyclohexanediol diacrylate, 2,2-dimethylol propane diacrylate, glycerol diacrylate, tripropylene glycol diacrylate, glycerol triacrylate, 2,2-di(p-hydroxyphenyl)-propane dimethacrylate, triethylene glycol diacrylate, polyoxyethyl-2-2-di(p-hydroxyphenyl)-propane dimethacrylate, triethylene glycol dimethacrylate, polyoxypropyltrimethylol propane triacrylate, ethylene glycol dimethacrylate, butylene glycol dimethacrylate, 1,3-propanediol dimethacrylate, 1,2,4-butanetriol trimethacrylate, 2,2,4-trimethyl-1,3-pentanediol dimethacrylate, pentaerythritol trimethacrylate, 1-phenyl ethylene-1,2-dimethacrylate, pentaerythritol tetramethacrylate, trimethylol propane trimethacrylate, 1,5-pentanediol dimethacrylate, 1,4-benzenediol dimethacrylate, 2-acetoacetoxyethylmethacrylate, 2-acetoacetoxyethylacrylate, 3-acetoacetoxypropylmethacrylate, 3-acetoacetoxypropylacrylate, 2-acetoacetoamidoethylmethacrylate, and 2-acetoacetoamidoethylacrylate; aromatic vinyl compounds such as styrene, a-methylstyrene, dimethylstyrene, trimethylstyrene, ethylstyrene, isopropylstyrene, o-methoxystyrene, m-methoxystyrene, p-methoxystyrene, o-vinyltoluene, m-vinyltoluene, p-vinyltoluene, o-vinylbenzyl methyl ether, m-vinylbenzyl methyl ether, p-vinylbenzyl methyl ether, o-vinylbenzyl glycidyl ether, m-vinylbenzyl glycidyl ether, p-vinylbenzyl glycidyl ether, acetoxystyrene, chlorostyrene, dichlorostyrene, bromostyrene, vinylbenzoic acid methyl ester, etc., divinylbenzene, and vinyl toluene and vinyl esters, such as vinyl acrylate and vinyl methacrylate, and the like.

By the term “aryl” is meant a radical derived from an aromatic hydrocarbon by the elimination of one atom of hydrogen and can be substituted or unsubstituted. The aromatic hydrocarbon can be mononuclear or polynuclear. Examples of aryl of the mononuclear type include phenyl, tolyl, xylyl, mesityl, cumenyl, and the like. Examples of aryl of the polynuclear type include naphthyl, anthryl, phenanthryl, and the like. The aryl group can have at least one substituent selected from, as for example, halogen, hydroxy, cyano, carboxy, nitro, amino, lower alkyl, lower alkoxy, and the like.

As used herein, the term “alkaryl” means an aryl group bearing an alkyl group; the term “aralkyl” means an alkyl group bearing an aryl group; the term “arylalkaryl” means an aryl group bearing an alkyl group bearing an aryl group

By the term “carbocyclic ring” is meant an unsubstituted or substituted, saturated, unsaturated or aromatic, hydrocarbon ring radical. Carbocyclic rings are monocyclic or are fused, bridged or spiro polycyclic ring systems. Examples include norbornene, adamantane, and tetracyclododecene. The substituents on the carbocyclic ring may be aliphatic or cycloaliphatic alkyls, esters, acids, hydroxyl, nitrile, alkyl derivatives, and the like.

As used herein, “aralkyloxy” is an oxygen radical having an aralkyl substituent.

As used herein, “aryloxy” is an oxygen radical having an aryl substituent (i.e., —O-aryl).

Other examples of resin binders include a photopolymerizable compound containing at least two pendant unsaturated groups, such as, for example, styrene/maleic anhydride oligomers which have been partially esterified with ethylenic unsaturation, preferably, acrylic or methacrylic functionality. A typical styrene/maleic anhydride oligomer is a copolymer of styrene and maleic anhydride with a mole ratio of about 1:1 but can range from 1:4 to 4:1. The styrene/maleic anhydride oligomer is available, for example as SMA-1000, SMA-2000, and SMA-3000 (Sartomer Company) and are described in U.S. Pat. Nos. 3,825,430; 4,820,773; and 6,074,436, the contents relating to such styrene/maleic anhydride resins being incorporated by reference. The styrene/maleic anhydride oligomer can then be reacted with, for example, a hydroxyalkylacrylyl or HO—X, where X is defined above (examples of which include hydroxyethyl acrylate, hydroxyethyl methacrylate, hydroxypropyl acrylate, hydroxypentyl methacrylate). This kind of reaction is described in, for example, U.S. Pat. No. 3,825,430. Styrene/maleic anhydride half-ester oligomers are also available from Sartomer Company under the SARBOX® tradename.

Other examples of resin binders include those found in U.S. Pat. Nos. 4,722,947; 4,745,138; 5,137,952: 6,329,123; 6,262,132; 4,491,628; 6,358,665 (which also provides further examples of photoacid generators); 6,576,394, and 3,825,430, the contents of which are hereby incorporated herein by reference. Further examples include t-butyloxycarbonyl p-hydroxystyrene/p-hydroxystyene; acrylate (or methacrylate)/p-hydroxystyrene copolymers; acrylate (or methacrylate)/p-hydroxystyrene/styrene copolymers; cycloolefin-based polymers; and acrylate (or methacrylate) based polymers. Other examples are also found in co-pending U.S. Pat. No. 7,078,157, the contents of which are hereby incorporated herein by reference. One resin of interest is one of the formula:

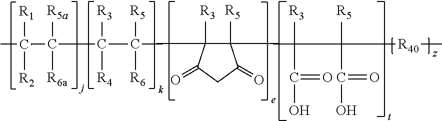

wherein R₁ and R₂ may be the same or different and each may independently be selected from the group consisting of hydrogen, C₁₋₅₀ alkyl, C₆₋₂₀ aryl, C₁₋₂₀ alkaryl, C₁₋₂₀ aralkyl, C₁₋₁₀ alkoxy, C₃₋₁₈ cycloalkyl, C₂₋₂₀ alkenyl, 2,3-epoxy propyl, cyano, and halogen, the C₁₋₅₀ alkyl, C₈₋₂₀ aryl, C₁₋₂₀ alkaryl, C₁₋₂₀ aralkyl, C₁₋₁₀ alkoxy, C₃₋₁₈ cycloalkyl, and C₂₋₂₀ alkenyl being unsubstituted or substituted by one or more C₃₋₁₂ cycloalkyl, cyano, C₁₋₅ alkyl, C₁₋₅ alkoxy, C₆₋₂₀ aryloxy, C₁₋₂₀ aralkyloxy, 2,3-epoxy propyl, hydroxyl, or halogen groups;

R₃ is selected from the group consisting of hydrogen, C₁₋₅₀ alkyl, C₈₋₂₀ aryl, C₁₋₂₀ alkaryl, C₁₋₂₀ aralkyl, C₃₋₁₈ cycloalkyl, C₂₋₂₀ alkenyl, cyano, 2,3-epoxy propyl, and halogen, the C₁₋₅₀ alkyl, C₈₋₂₀ aryl, C₁₋₂₀ alkaryl, C₁₋₂₀ aralkyl, C₃₋₁₈ cycloalkyl, and C₂₋₂₀ alkenyl being unsubstituted or substituted by one or more C₃₋₁₂ cycloalkyl, cyano, C₁₋₆ alkyl, C₁₋₆ alkoxy, C₆₋₂₀ aryloxy, C₁₋₂₀ aralkyloxy, 2,3-epoxy propyl, hydroxyl, or halogen groups;

R₄, R₆, and R₆ₐ may be the same or different and each may independently be selected from the group consisting of hydrogen, cyano, C₁₋₅₀ alkyl, C₆₋₂₀ aryl, C₁₋₂₀ alkaryl, C₁₋₂₀ aralkyl, C₃₋₁₈ cycloalkyl, C₂₋₂₀ alkenyl, halogen, an oxyalkylated group containing from 2 to 4 carbon atoms in each oxyalkylated group, which group may be of 1 to 20 repeating units and which terminates with hydrogen or C₁₋₄ alkyl, X, and —(CH₂)ₙ—C(═O)—OR₇, where R₇ is selected from hydrogen, C₁₋₅₀ alkyl, C₆₋₂₀ aryl, C₁₋₂₀ alkaryl, C₁₋₂₀ aralkyl, C₂₋₂₀ alkenyl, C₅₋₅₀ carbocyclic ring, NR₇ₐR_{7b}, 2,3-epoxy propyl, n is a whole number from 0 to 3, the C₁₋₅₀ alkyl, C₆₋₂₀ aryl, C₁₋₂₀ alkaryl, C₁₋₂₀ aralkyl, C₃₋₁₆ cycloalkyl, C₂₋₂₀ alkenyl, and C₅₋₅₀ carbocyclic ring being unsubstituted or substituted by one or more C₃₋₁₂ cycloalkyl, cyano, C₁₋₅ alkyl, C₁₋₆ alkyoxy, C₆₋₂₀ aryloxy, C₁₋₂₀ aralkyloxy, 2,3-epoxy propyl, hydroxyl, or halogen groups, each of R₇ₐ and R_{7b} are independently hydrogen or C₁₋₂₀ alkyl and X is —C(═O)—R₁₀ or —R₆₀—C(═O)—CH₂—R₇₀ where R₁₀ is selected from the group consisting of —O—R₁₁-O—C(═O)—C(R₁₂)═C H₂, —O—R₁₁—NH—O—C(O)—C(R₁₂)═CH₂, and —NH—R₁₁—O—C(═O)—C(R₁₂)═CH₂, where R₁₁ is a linear or branched divalent C₁₋₄₀ alkylene or an oxyalkylated derivative thereof containing from 2 to 4 carbon atoms in each oxylalkylated group, which group may be of 1 to 20 repeating units; R₆₀ is —C(═O)—W—R₁₁—V—; each of W and V are independently selected from O, S or NR₁₀₀ where R₁₀₀ is hydrogen or C₁₋₆ alkyl; R₁₁ is as above, R₇₀ is —C(═O)—R₅₀ or -cyano, where R₅₀ is hydrogen or C₁₋₁₀ alkyl;

R₁₂ is hydrogen or C₁₋₅ alkyl;

R₅ and R₅ₐ may be the same or different and each may be independently selected from the group consisting of hydrogen, C₁₋₅₀ alkyl, C₆₋₂₀ aryl, C₁₋₂₀ alkaryl, C₁₋₂₀ aralkyl, C₃₋₁₈ cycloalkyl, C₂₋₂₀ alkenyl, cyano, 2,3-epoxy propyl, halogen and carboxy, the C₁₋₅₀ alkyl, C₆₋₂₀ aryl, C₁₋₁₈ alkaryl, C₁₋₂₀ aralkyl, C₂₋₂₀ alkenyl, and C₃₋₁₂ cycloalkyl being unsubstituted or substituted by one or more C₃₋₁₂ cycloalkyl, cyano, C₁₋₅ alkyl, C₁₋₆ alkoxy, C₆₋₂₀ aryloxy, C₁₋₂₀ aralkyloxy, 2,3-epoxy propyl, hydroxyl, or halogen groups; and

R₄₀ is any monomer that is copolymerizable with moieties found in [ ]ₖ, [ ]ₑ, and/or [ ]ₜ, including those moieties identified for [ ]ⱼ, [ ]ₖ, [ ]ₑ, and/or [ ]ₜ; and j, k, e, t, and z are each whole numbers such that the sum of j, k, e, t, and z ranges from about 2 to about 20, with j and k each being equal to or greater than 1, and z, e and/or t may be zero.

Preferable embodiments of this compound include those wherein either R₁ is hydrogen and R₂ is C_{6-10 20} aryl unsubstituted or substituted by one or more C₃₋₁₂ cycloalkyl, C₁₋₆ alkoxy, 2,3-epoxy propyl, hydroxyl, cyano, C₁₋₅ alkyl, or halogen groups; R₅ₐ is hydrogen; R₆ₐ is hydrogen; R₃ is hydrogen; R₄ in is —(CH₂)ₙ—C(═O)—OR₇, where R₇ is hydrogen, and n is 0; R₅ is hydrogen; R₆ in is X where X is —C(═O)—R₁₀ where R₁₀ is —O—R₁₁-O—C(═)—C(R₁₂)═CH₂, R₁₁ is a C₂ alkylene, R₁₂ is hydrogen; e and t are each not zero, and z is zero; or

R₁ is hydrogen and R₂ is C_{6-10 20} aryl unsubstituted or substituted by one or more C₃₋₁₂ cycloalkyl, C₁₋₆ alkoxy, 2,3-epoxy propyl, hydroxyl, cyano, C₁₋₅ alkyl, or halogen groups; R₅ₐ is hydrogen; R₆ₐ is hydrogen; R₃ is hydrogen; R₄ in is —(CH₂)ₙ—C(═O)—OR₇, where R₇ is hydrogen, and n is 0; R₅ is hydrogen; R₆ in is X where X is —C(═O)—R₁₀ where R₁₀ is —O—R₁₁—O—C(═O)—C(R₁₂)═CH₂, R₁₁ is a C₂ alkylene, R₁₂ is hydrogen; each of e, t and z are not zero; and R₄₀ is

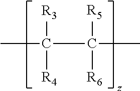

where R₃ in [ ]_{z} and R₅ in [ ]_{z} are hydrogen, R₄ in [ ]_{z} is —(CH₂)ₙ—C(═O)—OR₇, where R₇ is hydrogen, n is 0; R₆ in [ ]_{z} is —(CH₂)ₙ—C(═O)—OR₇, where R₇ is C₁₋₅₀ alkyl substituted by C₁₋₆ alkoxy, and n is 0; or

R₁ is hydrogen and R₂ is C_{6-10 20} aryl unsubstituted or substituted by one or more C₃₋₁₂ cycloalkyl, C₁₋₆ alkoxy, 2,3-epoxy propyl, hydroxyl, cyano, C₁₋₅ alkyl, or halogen groups; R₅ₐ is hydrogen; R₆ₐ is hydrogen; R₃ is hydrogen; R₄ in is —(CH₂)ₙ—C(═O)—OR₇, where R₇ is hydrogen, and n is 0; R₅ is hydrogen; R₆ in is X where X is —C(═O)—R₁₀ where R₁₀ is —O—R₁₁-O—C(═O)—C(R₁₂)═CH₂, R₁₁ is a C₂ alkylene, R₁₂ is hydrogen; and each of e, t and z are each zero.

The amount of resin binder in the composition ranges from about 30 to about 55% by weight, and more typically from about 35 to about 50% by weight by total solids.

Certain compositions of the present invention also contain at least one ethylenically unsaturated photopolymerizable polyalkylene oxide hydrophilic monomer which typically crosslinks by photo-induced free radical polymerization forming the desired insoluble pattern. The polyalkyene oxide segment should typically be long enough to render a certain degree of aqueous solubility, but not too long to compromise physical-chemical properties of the crosslinked material to be able to withstand a post image process such as metal plating. Herein, alkylene oxide refers to ethylene or propylene oxide and poly- means 1 or more, for example 1 to 100, more preferably 2 to 10.

The hydrophilic polyalkylene oxide monomer typically has a multi (that is, 2 or more) α,β-ethylenically unsaturated function and from 2 to 10 ethylene oxide or propylene oxide units. In such monomers, the α,β-ethylenically unsaturated moieties, typically acrylic or methacrylic units, are esterified with the alkylene oxide units. The ethylene and/or propylene oxide units render the monomers hydrophilic and therefore more compatible with the aqueous developer. Ethylene oxide units are preferred to propylene oxide units as they are more hydrophilic. If propylene oxide units are used, typically a greater number of such units are used per monomer molecule than if ethylene oxide units were used.

Examples of the at least one ethylenically unsaturated photopolymerizable polyalkylene oxide hydrophilic monomer include, but are not limited to, diethylene glycol diacrylate, triethylene glycol diacrylate, diethylene glycol dimethacrylate, Methylene glycol dimethacrylate, tripropylene glycol diacrylate, tripropylene glycol dimethacrylate, tetraethylene glycol diacrylate, tetraethylene glycol dimethacrylate, pentaethylene glycol diacrylate, pentaethylene glycol dimethacrylate, pentapropylene glycol diacrylate, pentapropylene glycol dimethacrylate, propoxylated (3) trimethylolpropane triacrylate, propoxylated (6) trimethylolpropane triacrylate, ethoxylated (3) trimethylolpropane triacrylate, ethoxylated (6) trimethylolpropane triacrylate, ethoxylated (9) trimethylolpropane triacrylate, propoxylated trimethylolpropane triacrylates, propoxylated trimethylolpropane trimethacrylates, ethoxylated (2) bisphenol A dimethacrylate, ethoxylated (3) bisphenol A diacrylate, ethoxylated (4) bisphenol A dimethacrylate, ethoxylated (8) bisphenol A diacrylate, ethoxylated (4) bisphenol A diacrylate, ethoxylated (6) bisphenol A diacrylate, ethoxylated (6) bisphenol A dimethacrylate, propoxylated (2) neopentyl glycol diacrylate, propoxylated (3) glyceryl triacrylate, polyethylene glycol diacrylates, polyethylene glycol dimethacrylates, polypropylene glycol diacrylates, polypropylene glycol dimethacrylates, ethoxylated (4) pentaerythritol tetraacrylate, highly propoxylated (5.5) glyceryl triacrylate, ethoxylated glyceryl triacrylate, and propoxylated (3) glyceryl triacrylate, and the like. Examples of the foregoing can be obtained from Sartomer Company (Exton, Pa.). Further examples of hydrophilic polyalkylene oxide monomers can be found in U.S. Pat. Nos. 3,368,900, 3,380,831, and 4,180,474.

The amount of the hydrophilic polyalkylene oxide monomer, when used, is typically present in the composition in amounts of from about 5 to about 35% by weight, and more typically about 10 to about 20% by weight in the composition.

Other examples of resin binder and cross-linking agent compositions include a novolak resin with an aminoplast cross-linking agent; acid functional polymers combined with non-acid functional monomers, and the like.

Certain compositions of the present invention also contain least one photoinitiator. Suitable photoinitiators include, for example, 9-phenyl acridine, 9-phenyl acridine homologues (such as those described in U.S. Pat. No. 5,217,845, which is incorporated herein by reference; examples of which include 2,7-dibenzoyl-9-phenylacridine, 2,7-bis(α-hydroxybenzyl)-9-phenylacridine, 2,7-bis(α-acetoxybenzyl)-9-phenylacridine, 2,7-dimethyl-9-(4-methylphenyl)acridine, 2,7-dimethyl-9-phenylacridine, 2,7-bis(3,4-dimethylbenzoyl)-9-(3,4-dimethylphenyl)acridine, 2,7-bis(α-acetoxy-4-tertbutylbenzyl)-9-(4-tert-butylphenyl)acridine, 2,7-dimethyl-9-(3,4-dichlorophenyl)acridine, 2,7-dimethyl-9-(4-benzoylphenyl)acridine, 2,7-bis(2-chlorobenzoyl)-9-(2-chlorophenyl)acridine, 2-(α-hydroxy-3-bromobenzyl)-6-methyl-9-(3-bromophenyl)acridine, 2,5-bis(4-tert-butylbenzoyl)-9-(4-tertbutylphenyl)acridine, 1,4-bis(2,7-dimethyl-9-acridinyl)benzene, 2,7-bis(α-phenylaminocarbonyloxy-3,4-dimethylbenzyl)-9-(3,4-dimethyl phenyl)acridine and 2,7-bis(3,5-dimethyl-4-hydroxy-4′-fluorodiphenylmethyl)-9-(4-fluorophenyl)acridine), acyloins (e.g., benzoin, pivaloin, and the like), acyloin ethers (e.g., benzoin methyl ether, benzoin ethyl ether, benzoin propyl ether, and the like), a-diketone compounds or monoketal derivatives thereof (e.g., diacetyl, benzil, benzyl dimethyl ketal, and the like), hydrogen abstraction-type initiators (e.g., xanthone, thioxanthone, 2-isopropylthioxanthone, 4-isopropylthioxanthone, 2-chlorothioxanthone, 2-methylthioxanthone, benzil, benzophenone, acetophenones, 2,2-diethoxyacetophenone, 2-hydroxy-2-methylpropiophenone, 4-isopropyl-2-hydroxy-2-methylpropiophenone, and 1,1-dichloroacetophenone, 4,4′bis(N,N′-dimethylamino)benzophenone, polynuclear quinones (e.g., 9,10-anthraquinone, 9,10-phenanthrenequinone, 2-ethyl anthraquinone, 1,4-naphthoquinone), and the like), acyl phosphine oxides, and the like, as well as mixtures of any two or more thereof. Further examples of photoinitiators include 2,4-bis-trichloromethyl-6-(3-bromo-4-methoxy)phenyl-s-triazine, 2,4-bis-trichloromethyl-6-(2-bromo-4-methoxy)-phenyl-s-triazine, 2,4-bis-trichloromethyl-6-(3-bromo-4-methoxy)styrylphenyl-s-triazine, 2,4-bis-trichloromethyl-6-(2-bromo-4-methoxy)styrylphenyl-s-triazine, bis(cyclopentadienyl)-bis[2,6-di-fluoro-3-(pyrr-1-yl)phenyl]titanium, bis(cyclopentadienyl)bis[2,6-difluoro-2-(pyrr-1-yl)phenyl]titanium, bis(cyclopentadienyl)-bis(2,3,4,5,6-pentafluorophenyl)titanium, bis-(cyclopentadienyl)-bis[2,5-difluoro-3-(pyrr-1-yl)phenyl]-titanium, 1-hydroxycyclohexyl phenyl ketone, 2,2-dimethoxy-1,2-diphenylethan-1-one, 2-methyl-1-[4-(methylthio)phenyl]-2-morpholinopropan-1-one, 2-benzyl-2-dimethylamino-1-(4-morpholinophenyl)-butan-1-one, 2-hydroxy-2-methyl-1-phenylpropan-1-one, 2,4,6-trimethylbenzoyldiphenylphosphine oxide, 1-[4-(2-hydroxyethoxy)phenyl]-2-hydroxy-2-methyl-1-propan-1-one, 2,4-diethylthioxanthone, 2,4-dimethylthioxanthone, 1-chloro-4-propoxythioxanthone, 3,3-dimethyl-4-methoxybenzophenone, 1-(4-isopropylphenyl)-2-hydroxy-2-methylpropan-1-one, 1-(4-dodecylphenyl)-2-hydroxy-2-methylpropan-1-one, 4-benzoyl-4′-methyldimethylsulfide, 4-dimethylaminobenzoic acid, methyl 4-dimethylaminobenzoate, ethyl 4-dimethylaminobenzoate, n-butyl 4-dimethylaminobenzoate, 2-ethylhexyl-4-dimethylaminobenzoate, 2-isoamyl-4-dimethyl aminobenzoate, 2,2-diethoxyacetophenone, benzyl β-methoxyethyl acetal, 1-phenyl-1,2-propanedi-one-2-(o-ethoxycarbonyl)oxime, methyl o-benzoylbenzoate, bis(4-dimethylaminophenyl)ketone, p-dimethylaminoacetophenone, p-tert-butyl-trichloroacetophenone, p-tert-butyl-dichloro-acetophenone, dibenzosuberone, α,α-dichloro-4-phenoxyacetophenone, pentyl 4-dimethylaminobenzoate, 2-(o-chlorophenyl)-4,5-diphenylimidazolyl dimer, α,α-d ialkoxyacetophenones, α-hydroxy alkylphenones, α-aminoalkylphenones, and the like, as well as mixtures thereof.

The amount of the photoinitator, when used in the composition, typically ranges from about 0.01 to about 4% by weight and more typically about 0.1 to about 1% by weight in the composition.

Certain compositions of the present invention contain photoacid generators. Suitable examples of the photoacid generator include onium salts, diazomethane derivatives, glyoxime derivatives, beta.-ketosulfone derivatives, disulfone derivatives, 2-nitrobenzylsulfonate derivatives, sulfonic acid ester derivatives, and imidoyl sulfonate derivatives.

Illustrative examples of the photoacid generator include:

onium salts such as diphenyliodonium trifluoromethanesulfonate, (p-tert-butoxyphenyl)phenyliodonium trifluoromethanesulfonate, diphenyliodonium p-toluenesulfonate, (p-tert-butoxyphenyl)phenyliodonium p-toluenesulfonate, triphenylsulfonium trifluoromethanesulfonate, (p-tert-butoxyphenyl)diphenylsulfonium trifluoromethanesulfonate, bis(p-tert-butoxyphenyl)phenylsulfonium trifluoromethanesulfonate, tris(p-tert-butoxyphenyl)-sulfonium trifluoromethanesulfonate, triphenylsulfonium p-toluenesulfonate, (p-tert-butoxyphenyl)diphenylsulfonium p-toluenesulfonate, bis(p-tert-butoxyphenyl)phenylsulfonium p-toluenesulfonate, tris(p-tert-butoxyphenyl)sulfonium p-toluenesulfonate, triphenylsulfonium nonafluorobutanesulfonate, triphenylsulfonium butanesulfonate, trimethylsulfonium trifluoromethanesulfonate, trimethylsulfonium p-toluenesulfonate, cyclohexylmethyl(2-oxocyclohexyl)sulfonium trifluoromethanesulfonate, cyclohexylmethyl(2-oxocyclohexyl)sulfonium p-toluenesulfonate, dimethylphenylsulfonium trifluoromethanesulfonate, dimethylphenylsulfonium p-toluenesulfonate, dicyclohexylphenylsulfonium trifluoromethanesulfonate, and dicyclohexylphenylsulfonium p-toluenesulfonate; diazomethane derivatives such as bis(benzenesulfonyl)diazomethane, bis(p-toluenesulfonyl)diazomethane, bis(xylenesulfonyl)diazomethane, bis(cyclohexylsulfonyl)diazomethane, bis(cyclopentylsulfonyl)diazomethane, bis(n-butylsulfonyl)diazomethane, bis(isobutylsulfonyl)diazomethane, bis(sec-butylsulfonyl)diazomethane, bis(n-propylsulfonyl)diazomethane, bis(isopropylsulfonyl)diazomethane, bis(tert-butylsulfonyl)diazomethane, bis(n-amylsulfonyl)diazomethane, bis(isoamylsulfonyl)diazomethane, bis(sec-amylsulfonyl)diazomethane, bis(tert-amylsulfonyl)diazomethane, 1-cyclohexylsulfonyl-1-(tert-butylsulfonyl)diazomethane, 1-cyclohexylsulfonyl-1-(tert-amylsulfonyl)diazomethane, and 1-tert-amylsulfonyl-1-(tert-butylsulfonyl)diazomethane;

glyoxime derivatives such as bis-o-(p-toluenesulfonyl)-.alpha.-dimethylglyoxime, bis-o-(p-toluenesulfonyl)-.alpha.-diphenylglyoxime, bis-o-(p-toluenesulfonyl)-.alpha.-dicyclohexylglyoxime, bis-o-(p-toluenesulfonyl)-2,3-pentanedioneglyoxime, bis-o-(p-toluenesulfonyl)-2-methyl-3,4-pentanedioneglyoxime, bis-o-(n-butanesulfonyl)-a-dimethylglyoxime, bis-o-(n-butanesulfonyl)-.alpha.-diphenylglyoxime, bis-o-(n-butanesulfonyl)-.alpha.-dicyclohexylglyoxime, bis-o-(n-butanesulfonyl)-2,3-pentanedioneglyoxime, bis-o-(n-butanesulfonyl)-2-methyl-3,4-pentanedioneglyoxime, bis-o-(methanesulfonyl)-.alpha.-dimethylglyoxime, bis-o-(trifluoromethanesulfonyl)-.alpha.-dimethyl glyoxime, bis-o-(1,1,1-trifluoroethanesulfonyl)-.alpha.-dimethylglyoxime, bis-o-(tert-butanesulfonyl)-.alpha.-dimethylglyoxime, bis-o-(perfluorooctanesulfonyl)-.alpha.-dimethylglyoxime, bis-o-(cyclohexanesulfonyl)-.alpha.-dimethylglyoxime, bis-o-(benzenesulfonyl)-.alpha.-dimethylglyoxime, bis-o-(p-fluorobenzenesulfonyl)-.alpha.-dimethylglyoxime, bis-o-(p-tert-butylbenzenesulfonyl)-.alpha.-dimrthylglyoxime, bis-o-(xylenesulfonyl)-.alpha.-dimethylglyoxime, and bis-o-(camphorsulfonyl)-.alpha.-dimethylglyoxime;

beta.-ketosulfone derivatives such as 2-cyclohexylcarbonyl-2-(p-toluenesulfonyl)propane and 2-isopropylcarbonyl-2-(p-toluenesulfonyl)propane;

disulfone derivatives such as diphenyl disulfone and dicyclohexyl disulfone;

2-nitrobenzyl sulfonate derivatives such as 2,6-dinitrobenzyl p-toluenesulfonate and 2,4-dinitrobenzyl p-toluenesulfonate;

sulfonic acid ester derivatives such as 1,2,3-tris(methanesulfonyloxy)benzene, 1,2,3-tris(trifluoromethanesulfonyloxy)benzene, and 1,2,3-tris(p-toluenesulfonyloxy)benzene; and

imidoyl sulfonate derivatives such as phthalimidoyl triflate, phthalimidoyl tosylate, 5-norbornene-2,3-dicarboxyimidoyl triflate, 5-norbornene-2,3-dicarboxyimidoyl tosylate, and 5-norbornene-2,3-dicarboxyimidoyl n-butylsulfonate.

The use and development of such photoacid generators is well known to those skilled in the art.

Other compositions according to the present invention can also include one or more components selected from at least one amine modified acrylic oligomer, dyes, adhesion promoters, nonionic surfactants (both fluorinated and non-fluorinated), leveling agents, photosensitizers, solvents and the like. These materials are well known to those of ordinary skill in the art.

Certain compositions of the present invention may also contain as part of the resin binder system, an amine modified acrylic oligomer (also known as acrylated amines) as an auxiliary photopolymerizable compound. Some examples of typical amine modified acrylic oligomers can be represented by, for example, one of the following formulae:

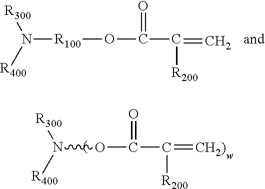

wherein R₁₀₀ is C₁₋₁₀ alkyl, -(EO)ₐₐ-, -(PO)ₐₐ— or

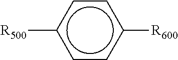

where EO is ethylene oxide, PO is propylene oxide, aa is an integer from 1 to 10, R₅₀₀ and R₆₀₀ each may be the same or different and each independently are C₁₋₁₀ alkyl; R₂₀₀ is hydrogen or C₁₋₆ alkyl, and R₃₀₀ and R₄₀₀ each may be the same or different and each independently hydrogen or C₁₋₁₈ alkyl, the alkyl being unsubstituted or substituted with at least one member selected from the group consisting of haloalkyl, C₁₋₄ alkoxyl, carboxyl, amino, hydroxyl, aryl, sulfonyl, alkoxycarbonyl, aminocarbonyl; and w is an integer from 1 to 10. The amine acrylic oligomer typically has a molecular weight of about 200 to about 2,000. The amine acrylic oligomer can also contain polyalkylene oxide moieties. Some examples of commercially available amine modified acrylate oligomers include Ebecryl® 81, Ebecryl® 83, Ebecryl® 7100 (UCB Chemicals, Smyrna, Ga.), Laromer® PO 77F (LR 8946), Laromer® PO 94 F (LR 8894), Laromer® LR 8956, Laromer® LR 8996 (BASE, Mt. Olive, N.J.), Actilane 584, Actilane 587, Actilane 595 (Akcros Chemicals, a division of Akzo Nobel NV) and CN501, CN502, CN550, CN551, CN371, CN381, CN383, CN384, CN385 (Sartomer Company, Exton, Pa.).

The amine modified acrylic oligomer, when present in the composition, typically ranges from about 0.1 to about 20% by weight and more typically about 0.5 to about 10% by weight.

Examples of solvents include, for example, a glycol ether derivative such as ethyl cellosolve, methyl cellosolve, propylene glycol monomethyl ether, diethylene glycol monomethyl ether, diethylene glycol monoethyl ether, dipropylene glycol dimethyl ether, propylene glycol n-propyl ether, or diethylene glycol dimethyl ether; a glycol ether ester derivative such as ethyl cellosolve acetate, methyl cellosolve acetate, or propylene glycol monomethyl ether acetate; carboxylates such as ethyl acetate, n-butyl acetate and amyl acetate; carboxylates of di-basic acids such as diethyloxylate and diethylmalonate; dicarboxylates of glycols such as ethylene glycol diacetate and propylene glycol diacetate; and hydroxy carboxylates such as methyl lactate, ethyl lactate, ethyl glycolate, and ethyl-3-hydroxy propionate; a ketone ester such as methyl pyruvate or ethyl pyruvate; an alkoxycarboxylic acid ester such as methyl 3-methoxypropionate, ethyl 3-ethoxypropionate, ethyl 2-hydroxy-2-methylpropionate, or methylethoxypropionate; a ketone derivative such as methyl ethyl ketone, acetyl acetone, cyclopentanone, cyclohexanone or 2-heptanone; a ketone ether derivative such as diacetone alcohol methyl ether; a ketone alcohol derivative such as acetol or diacetone alcohol; lactones such as butyrolactone; an amide derivative such as dimethylacetamide or dimethylformamide, anisole, and mixtures thereof. The amount of solvent(s), when present in the composition, typically ranges from about 30 to about 80% by weight.

Another component of the positive photoresist composition is an inorganic particle material. The inorganic particle is one which increases the dry etch resistance of the coating in plasma gases, such as those comprising chlorine. Suitable inorganic particle materials which can be used include metals, metal salts, metallic oxides, and combinations thereof. Suitable metals are such as those in Groups VIIB, VIIB, VIIIB, IB, IIB, IIA, IVA, VA, VIA of the periodic table of elements and combinations thereof. Suitable examples of metals include titanium, vanadium, cobalt, hafnium, boron, gold, silver, silicon, aluminum, copper, zinc, gallium, magnesium, indium, nickel, germanium, tin, molybdenum, niobium, zirconium, platinum, palladium, antimony, and combinations thereof. Suitable examples of metal salts include halides, carbides and nitrides, such as silicon carbide, silicon nitride and combinations thereof. Examples of metallic oxides include those available from the Groups mentioned above and combinations thereof. Suitable examples include magnesium oxide, iron (III) oxide, aluminum oxide, chromium oxide, zinc oxide, titanium dioxide, silicon dioxide and combinations thereof. Specifically, metal oxides may be used; silicon dioxide as an example may be used as the nanoparticle. In general, the average particle size (diameter) of the inorganic particle is between about 1 and 100 nm, further between about 10 and about 50 nm, and further between about 10 and about 15 nm. Such particles may be spherical.

Typically the percentage content of the inorganic particle material is between about 0.1% and about 90% by weight of the photosensitive photoresist composition; further between about 5% and about 75% and further between about 10% and about 50% by weight.

In useful embodiments, when the inorganic particle material is added to a photoresist composition, it has been unexpectedly discovered that the combination of the inorganic particle material and the negative photoresist allows for the formation of thin photosensitive films with good lithographic properties.

Typically, the thickness of the photosensitive composition containing inorganic particle material on a substrate is between about 0.5 to about 5 μm, further between about 1 and about 4 μm, further between about 2 and about 4 μm, and even further between about 3 μm and 4 μm or between about 1 and about 2 μm.

For example, colloidal silica (SiO₂) can be prepared in 1 to 100 nm diameter particles, and is commercially available as 8-10 nm, 10-15 nm, 10-20 nm, 17-23 nm, and 40-50 nm particles. Such colloidal silicas are available from, for example, Nissan Chemicals. In some instances, the colloidal silicas are supplied in various solvents which are not very useful in the photoresist area. In most instances, it is beneficial to disperse the colloidal silica in a solvent which is useful, for example, propylene glycol mono-methyl ether, propylene glycol mono-methyl ether acetate, ethyl lactate, etc.

In the preferred embodiment, the solid parts of the photoresist composition preferably range from 95% to about 40% resin with from about 5% to about 50% photoactive component. A more preferred range of resin would be from about 50% to about 90% and most preferably from about 65% to about 85% by weight of the solid photoresist components. A more preferred range of the photoactive component would be from about 10% to about 40% and most preferably from about 15% to about 35%, by weight of the solid in the photoresist. Other additives such as colorants, non-actinic dyes, plasticizers, adhesion promoters, coating aids, sensitizers, crosslinking agents, surfactants, and speed enhancers may be added to the photoresist composition suitable for image-wise exposure and development as a positive photoresist before the solution is coated onto a substrate.

Suitable solvents for photoresists may include, for example, a glycol ether derivative such as ethyl cellosolve, methyl cellosolve, propylene glycol monomethyl ether, diethylene glycol monomethyl ether, diethylene glycol monoethyl ether, dipropylene glycol dimethyl ether, propylene glycol n-propyl ether, or diethylene glycol dimethyl ether; a glycol ether ester derivative such as ethyl cellosolve acetate, methyl cellosolve acetate, or propylene glycol monomethyl ether acetate; carboxylates such as ethyl acetate, n-butyl acetate and amyl acetate; carboxylates of di-basic acids such as diethyloxylate and diethylmalonate; dicarboxylates of glycols such as ethylene glycol diacetate and propylene glycol diacetate; and hydroxy carboxylates such as methyl lactate, ethyl lactate, ethyl glycolate, and ethyl-3-hydroxy propionate; a ketone ester such as methyl pyruvate or ethyl pyruvate; an alkoxycarboxylic acid ester such as methyl 3-methoxypropionate, ethyl 3-ethoxypropionate, ethyl 2-hydroxy-2-methylpropionate, or methylethoxypropionate; a ketone derivative such as methyl ethyl ketone, acetyl acetone, cyclopentanone, cyclohexanone or 2-heptanone; a ketone ether derivative such as diacetone alcohol methyl ether; a ketone alcohol derivative such as acetol or diacetone alcohol; lactones such as butyrolactone; an amide derivative such as dimethylacetamide or dimethylformamide, anisole, and mixtures thereof.

The prepared photoresist composition solution can be applied to a substrate by any conventional method used in the photoresist art, including dipping, spraying, whirling and spin coating. When spin coating, for example, the resist solution can be adjusted with respect to the percentage of solids content, in order to provide coating of the desired thickness, given the type of spinning equipment utilized and the amount of time allowed for the spinning process. Suitable substrates include, without limitation, silicon, aluminum, polymeric resins, silicon dioxide, metals, doped silicon dioxide, silicon nitride, tantalum, copper, polysilicon, ceramics, sapphire, aluminum/copper mixtures; gallium arsenide, SiC, GaN, and other such Group III/V compounds.

The novel photosensitive coatings produced by the described procedure are particularly suitable for application to substrates such as those which are utilized in the production of microprocessors and other miniaturized integrated circuit components. The substrate may also comprise various polymeric resins, especially transparent polymers such as polyesters. The substrate may have an adhesion promoted layer of a suitable composition, such as one containing hexa-alkyl disilazane.

The photoresist composition solution is then coated onto the substrate, and the substrate is treated at a temperature from about 50° C. to about 200° C. for from about 30 seconds to about 600 seconds (or even longer) on a hot plate or for from about 15 to about 90 minutes (or even longer) in a convection oven. This temperature treatment is selected in order to reduce the concentration of residual solvents in the photoresist, while not causing substantial thermal degradation of the solid components. In general, one desires to minimize the concentration of solvents and the above temperature treatment is conducted until substantially all of the solvents have evaporated and a coating of photoresist composition, on the order of about 1-5 microns (micrometer) in thickness, remains on the substrate. In a preferred embodiment the temperature is from about 95° C. to about 120° C. The treatment is conducted until the rate of change of solvent removal becomes relatively insignificant. The temperature and time selection depends on the photoresist properties desired by the user, as well as the equipment used and commercially desired coating times. The coating substrate can then be image-wise exposed to actinic radiation, e.g. ultraviolet radiation, at a wavelength of from about 157 nm to about 500 nm, X-ray, electron beam, ion beam or laser radiation, as well as other sub-200 nm wavelengths, in any desired pattern, produced by use of suitable masks, negatives, stencils, templates, etc. Generally, photoresist films are exposed using broadband radiation, using equipments such as Ultratech, Karl Süss or Perkin Elmer broadband exposure tools, although 436 nm, 365 nm, and 248 nm Steppers may also be used.

The photoresist is subjected to a post exposure second baking or heat treatment before development. The heating temperatures may range from about 90° C. to about 150° C., and more preferably from about 100° C. to about 130° C. The heating may be conducted for from about 30 seconds to about 2 minutes, and more preferably from about 60 seconds to about 90 seconds on a hot plate or about 30 to about 45 minutes by convection oven. The heating allows the regions exposed to the radiation to become crosslinked.

The exposed photoresist-coated substrates are developed to remove the unexposed areas by immersion in a developing solution or developed by spray development process. The solution is preferably agitated, for example, by nitrogen burst agitation. The substrates are allowed to remain in the developer until all of the photoresist coating has dissolved from the unexposed areas. Developers include aqueous solutions of ammonium or alkali metal hydroxides. One preferred aqueous developer is an aqueous solution of tetramethyl ammonium hydroxide. Other developers include solvent based developers. After removal of the patterned substrate from the developing solution, one may conduct an optional post-development heat treatment or bake to increase the coating's adhesion and chemical resistance to post imaging processing. The post-development heat treatment can comprise hot plate or oven baking of the coating and substrate below the coating's softening point or UV hardening process. The imaged substrate may then be coated with metals, or layers of metals to form bumps as is well known in the art, or processed further as desired. In a typical PSS or LED fabrication processes, wet or dry etch processes can be applied, where the patterned photoresist substrates are subjected to wet or dry etching; Buffered Oxide Etch:H₃PO₄/H₂SO₄ etch in wet etch processes or to chlorine containing gases like BCl₃/Cl₂ by reactive ion etch (RIE) in a dry etch process. In these processes the photoresist serves as the etch mask for underlying substrates used in LED fabrication to achieve the desired etched patterns, such as sapphire surface texture roughening or MESA GaN opening for subsequent metal contacts formation.

The following examples provide illustrations of the methods of producing and utilizing compositions of the present invention. These examples are not intended, however, to limit or restrict the scope of the invention in any way and should not be construed as providing conditions, parameters or values which must be utilized exclusively in order to practice the present invention. Unless otherwise specified, all parts and percents are by weight.

### EXAMPLES

Silica nanoparticles in ethylene glycol mono-n-propyl ether (NPC-ST-30, 10-15 nm in diameter, Snowtex, manufactured by Nissan Chemical Corp., 10375 Richmond Avenue, Suite 1000, Houston, Tex., a solid matter content of silica of 30-31% by weight) were used in the experiment. Commercial negative photoresists were obtained from AZ® Electronic Materials USA Corp., 70 Meister Ave., Somerville, N.J. and consisted of AZ® N4050 and AZ® N6070

### Formulation Example 1

### AZ® N4050-NC

### Preparation of Negative Nanocomposite Photoresist from Az® N4050

A solution was prepared by adding 8.4 g the NPC-ST-30 silica colloidal solution into 10 g of AZ® N4050 (39% solids content). The solution was rolled overnight at room temperature and used without filtration. The solution was transparent and the silica content was 40% by weight (solid matter base). This formulation was named AZ® N4050-NC. The silica nanoparticles formulated into the photoresist was named “AZ® N4050NC” and the particles were incorporated into the polymer matrices homogeneously without agglomeration. No precipitation was observed after 6 months.

### Formulation Example 2

### AZ® N6070-NC

### Preparation of Negative Nanocomposite Photoresist from Az® N6070

A solution was prepared by adding 8.6 g the NPC-ST-30 silica colloidal solution into 10 g of AZ® N6070 (70% solids content). The solution was rolled overnight at room temperature and used without filtration. The solution was transparent and the silica contents was 40% by weight (solid matter base). This formulation was named AZ® N6070-NC. The silica nanoparticles formulated into AZ® N6070 were incorporated into the polymer matrices homogeneously without agglomeration. No precipitation was observed after 6 months.

### Lithographic Example 1

The photoresist solution AZ® N4050-NC from formulation example 1 and AZ® N4050 were coated separately onto 6 inch silicon wafers at a spin speed of 800 rpm and baked at 110° C. for 60 seconds to give a coating of 3 μm. The wafers were exposed on an ASML i-line stepper(NA=0.48, σ=0.75, focus). The post exposure bake conditions were 110° C. for 30 seconds. The wafers were then developed in AZ® 300 MIF developer at 23° C. using two 50 second puddles.

The nanocomposite photoresist exhibited fast photospeed, good resolution and straight profile. When silica nanoparticles were dispersed homogeneously in polymer matrices, the polymer provided a protective layer which retarded dissolution of silica in the exposed parts. On the other hand, hydroxyl groups on the surface of silica nanoparticles (the hydrophilic surface) contributed to the high dissolution rate in the unexposed parts. Specifically, for 2 micron isolated trenches at a dose of 305 mJ/cm² AZ® N4050-NC gave a depth of focus of ˜4 micron comparable to that seen in the photoresist without nanoparticles, AZ® N4050, showing a slightly greater tendency for footing at the extremes of defocus compared to the photoresist without nanoparticles. Similarly, for 2 micron isolated trenches AZ® N4050-NC showed dose latitude ranging from 305 to 225 mJ/cm². This was the same as that of the photresist not containing the nanoparticles and only showed a slight profile sloping with a slight narrowing of the feature CD towards the bottom compared to the photoresist without the nanoparticles. Finally, the resolution of the nanocomposite photoresist exhibited resolution for isolated trenches down to 0.8 micron at a dose of 225 mJ/cm² and a defocus of 0 micron. This was the same as seen for AZ® N4050 without nanoparticles. The only difference observed was that the resist containing nanoparticles had some footing for the smallest feature (0.8 microns) compared to the resist without nanoparticles. Overall, the development of the 2 samples gave acceptable pattern profiles, showing that addition of nanoparticles to the photoresist did not degrade the lithographic performance.

### Lithographic Example 2

The photoresist solutions AZ® N6070-NC from formulation example 2 and AZ® N6070 were coated separately onto 6 inch silicon wafers at a spin speed of 3300 rpm and baked at 110° C. for 60 seconds to give a coating of 2 μm. The wafers were exposed on an ASML Hine stepper (NA=0.48, σ=0.75, focus). The post exposure bake conditions were 110° C. for 30 seconds. The wafers were then developed in AZ® 300 MIF developer at 23° C. using two 40 second puddles.

The nanocomposite photoresist exhibited fast photospeed, good resolution and straight profile. When silica nanoparticles were dispersed homogeneously in polymer matrices, the polymer provided a protective layer which retarded dissolution of silica in the exposed parts. On the other hand, hydroxyl groups on the surface of silica nanoparticles (the hydrophilic surface) contributed to the high dissolution rate in the unexposed parts. Specifically, for 1 μm lines (Line/Space=1/1) at a dose of 140 mJ/cm² AZ® N6070-NC gave a depth of focus of ˜1 μm compared to 1.5 μm in the photoresist without nanoparticles, AZ® N6070. Also, AZ® N6070-NC gave for 1.0 μm (post/space=1/1) posts a depth of focus of 2.5 microns at a dose of 140 mJ/cm². AZ® N6070-NC showed an exposure latitude ranging from 130 to 200 mJ/cm² compared to 100 mJ/cm² to 160 mJ/cm² for AZ® 6070 without nanoparticles. Similarly, AZ® N6070-NC gave for 1 μm posts (Post/space=1/1) a dose latitude ranging from 130 to 200 mJ/cm². Finally, the resolution for posts for the nanocomposite resist was down to 0.6 μm at a dose of 140 mJ/cm² and a defocus of 0.5 μm. Overall, the development of the 2 samples gave acceptable pattern profiles, showing that addition of nanoparticles to the photoresist did not degrade the lithographic performance.

### Etching Example 1

AZ® N4050-NC as described in formulation example 1 was spun (1800 rpm) onto a 8 inch wafer and post applied baked at 110° C. for 60 seconds to give a 2 μm thick film. Similarly AZ® N4050 was also spun as a 2 μm thick film onto a 8 inch wafer (2800 rpm) and using the same post applied bake. The etch process conditions were as follows: Using a NE-5000N (Ulvac) etcher at a pressure of 0.6 Pa, an antenna power of 50 W and a gas flow for Cl₂ of 40 SCCM, BCl₃ of 13 SCCM, and Ar of 13 SCCM the wafers were etched for 180 seconds.

Table 1 compares the etching results for the resist with an without nanoparticles. It can be seen that for these etching conditions, typically used for etching Sapphire, that AZ® N4050-NC gave a much slower etching rate than AZ® N4050.

TABLE 1

| Material | AZ ® N4050 | AZ ® N4050-NC |
|---|---|---|
| FT change | 0.2592 | 0.2240 |
| (um) before | | |
| and after | | |
| etching | | |
| Etch rate in | 864 | 747 |
| A/min | | |
| Normalized | 1 | 0.864 |
| etch rate | | |
| Silica % | 0 | 40 |

### Etching Example 2

AZ® N6070-NC as described in formulation example 2 was spun (3300 rpm) onto a 8 inch water and post applied baked at 110° C. for 60 seconds to give a 2 μm thick film. Similarly AZ® N6070 was also spun as a 2 μm thick film onto a 8 inch water (2500 rpm) and using the same post applied bake. The etch process conditions were as follows: Using a NE-5000N (Ulvac) etcher at a pressure of 0.6 Pa, an antenna power of 50 W and a gas flow for Cl₂ of 40 SCCM, BCl₃ of 13 SCCM, and Ar of 13 SCCM the wafers were etched for 180 seconds.

Table 2 compares the etching results for the resist with and without nanoparticles. It can be seen that for these etching conditions, typically used for etching Sapphire, AZ® N6070-NC gives a much slower etching rate than AZ® N6070.

TABLE 2

| Material | AZ ® N6070 | AZ ® N6070-NC |
|---|---|---|
| FT change | 0.2641 | 0.2276 |
| (um) | | |
| Etch rate in | 880.3 | 758.7 |
| A/min | | |
| Normalized | 1 | 0.862 |
| rate | | |
| Silica (%) | 0 | 40% |

### Etching Example 3

Table 3 gives a comparison of these resist with the Normalized etching rate we have found for the Sapphire substrate under these conditions for a variety of negative resists with 40% silica. In this table we have used the etching rate of the commercial resist AZ® GXR 601 as a benchmark for normalizing the rates observed. As can be seen all the negative resists with SiO₂ nanoparticles exhibited higher etch resistance than even the Sapphire substrate itself, which is desirable.

TABLE 3
Etching selectivity of Sapphire/resist

| Sample ID | | | N4050- |
|---|---|---|---|
| (40% silica) | GXR 601 | N6070-NC | NC |
| Normalized etch rate | 1 | 0.861 | 0.864 |
| Sapphire selectivity | 0.62 | 0.53382 | 0.53568 |
| per 1 um FT resist | | | |

Thus, a negative photosensitive composition with the nanoparticles gave higher etch resistance than without nanoparticles without losing the pattern lithographic performance.

We claim:

1. A negative photosensitive composition comprising a negative photoresist composition and an inorganic particle material having an average particle size equal to or less than 10 nanometers, wherein the thickness of the photosensitive coating film is less than 5 microns.

2. The negative photosensitive composition of claim 1 wherein the negative photoresist composition comprises (i) a resin binder, (ii) a photoacid generator, and (iii) a cross-linking agent.

3. The negative photosensitive composition of claim 1 wherein the negative photoresist composition comprises (i) a resin binder, (ii) optionally, addition-polymerizeable, ethylenically unsaturated compound(s) and (iii) a photoinitiator.

4. The negative photosensitive composition of claim 1 wherein the negative photoresist composition comprises (i) a photopolymerizable compound containing at least two pendant unsaturated groups; (ii) ethylenically unsaturated photopolymerizable polyalkylene oxide hydrophilic compound(s); and (iii) a photoinitiator.

5. The negative photosensitive composition according to claim 1, where the film has a thickness less than 4 microns.

6. The negative photosensitive composition according to claim 1, where the film has a thickness less than 3 microns.

7. The negative photosensitive composition according to claim 1, where the film has a thickness less than 2 microns.

8. The negative photosensitive composition according to claim 1, where the inorganic particle material is selected from a group consisting of colloidal silica, colloidal copper and colloidal TiO₂.

9. The negative photosensitive composition according to claim 1, where the inorganic colloidal particle material is SiO₂.

10. The negative photosensitive composition according to claim 1, where the inorganic particle material is SiO₂ and has an average particle size from about 5 to about 50 nanometers.

11. The photoresist composition according to claim 1, where the inorganic particle material has an average particle size from about 10 to about 15 nanometers.

12. The negative photosensitive composition according to claim 1, where the inorganic particle material is present in an amount of from about 0.1% and about 90% by weight of the photoresist.

13. The negative photosensitive composition according to claim 1, where the inorganic particle material is present in an amount of from about 5% and about 75% by weight of the photoresist.

14. The negative photosensitive composition according to claim 1, where the inorganic particle material is present in an amount of from about 10% and about 50% by weight of the photoresist.

15. The negative photosensitive composition according to claim 1 wherein the resin binder is a novolak resin.

16. A process for forming a negative photoresist image on a substrate, comprising the steps of:
a) coating the photoresist composition of claim 1 on a substrate, thereby forming a photoresist coating film with a thickness less than 5 microns;
b) imagewise exposing the coated substrate to radiation;
c) developing the unexposed substrate to form a photoresist image; and,
d) etching the substrate with a gas comprising chlorine, thereby forming a roughened substrate.

17. The process claim according to claim 16 where the substrate is selected from sapphire, SiC and GaN.
